(19) United States
(12) Patent Application Publication
(10) Pub. No.: US 2013/0061930 A1
(43) Pub. Date: Mar. 14, 2013

(54) SURFACE-MODIFIED ELECTRODE LAYERS IN ORGANIC PHOTOVOLTAIC CELLS

(71) Applicant: Pedro Atienzar, Valencia (ES)

(72) Inventor: Pedro Atienzar, Valencia (ES)

(73) Assignee: THE SOLAR PRESS UK LIMITED, London (GB)

(21) Appl. No.: 13/697,410

(22) PCT Filed: May 12, 2011
(86) PCT No.: PCT/GB2011/000724

§ 371 Date: Nov. 12, 2012

Related U.S. Application Data
(60) Provisional application No. 61/345,630, filed on May 18, 2010.

(30) Foreign Application Priority Data
Feb. 5, 2011 (GB) 10081446

(51) Int. Cl. H01L 51/46; H01L 51/48

(52) U.S. Cl. 136/263; 438/82; 257/E51.026

(57) ABSTRACT

An organic solar cell structure comprising at least one electrode which comprises a layer which is surface-modified with a dye is provided; said surface-modified layer being selected from a transparent conductor layer, a hole collecting layer (HCL), and an electron collecting layer (ECL). Uses of said solar cell structures and methods for their manufacture are also provided.

### TECHNICAL FIELD

This invention relates to organic photovoltaic (OPV) or organic photodetector (OPD) devices, such as organic solar cells.

### BACKGROUND

Photovoltaic cells convert radiation, for example visible light, into direct current (DC) electricity. Organic photovoltaic (OPV) cells are photovoltaic cells which comprise conductive organic polymers or small organic molecules, for light absorption, charge generation and charge transport. OPV cells find use in many applications, including solar panels and photodetectors. They may also be part of larger systems comprising other organic electronic devices, such as organic light emitting diodes (OLEDs) and organic thin film transistors (OTFTs).

The most common OPV structure is formed by a transparent conducting oxide (TCO) electrode, typically Indium Tin Oxide (ITO), an organic hole collecting layer (for example the doped polymer PEDOT:PSS), a photoactive layer, formed from a blend of donor and acceptor organic semiconductors, and the metallic contact, in some cases a thin interlayer of calcium or lithium fluoride (see FIG. 1).

In these devices the electrons are extracted by the metallic contact (the cathode) and the holes from the TCO (the anode). There are many variations on this structure that have been reported, including the use of alternative anodes to ITO (such as nanotube based dispersions), interlayers to confine charges and reduce dark currents, and printable silver cathodes.

More recently, a new architecture for OPV has been explored. The “inverted” OPV architecture is formed from a series of sequentially deposited layers (see FIG. 2). The first electrode deposited onto the substrate is formed from a transparent conductor, such as ITO. An electron collecting layer (ECL) may then be deposited onto this transparent conductor, if required. The photoactive layer is deposited on top of the lower electrode structure, and may consist of a blend or bilayer of donor and acceptor semiconductor materials. The hole collecting layer (HCL) is then deposited and may consist of a conductive polymer such as PEDOT:PSS or an inorganic material, such as a metal oxide. Finally, a high workfunction electrode is deposited onto the device stack.

In this “inverted” OPV architecture electrons are extracted from the TCO deposited on the substrate, rather than from the top metal electrode. Holes are collected at the top metal electrode, which has a high workfunction compared to the cathode in a conventional structure OPV device.

In this newer structure it is possible to use metal oxides that are more transparent in the visible range than PEDOT:PSS used in conventional OPV devices, leading to greater transmission of the visible light to the active layer. Also, the elimination of the low workfunction metal cathode from the device structure contributes to improved device stability.

Dye sensitised solar cells (DSSCs) have also been developed. With DSSCs, the dye is responsible for the light absorption. The dye usually sensitises a relatively thick film of porous titania.

US2008/149171 (Lu et al) discloses an inorganic photoelectrode with a novel anode structure, which allows rapid electron transport in the absence of charge traps. In some embodiments, a light-harvesting dye may optionally be added to the surface of the anode to enhance light absorption by the photoelectrode.

Lagemaat et al (Appl. Phys. Lett., 2006, 88, 233503) disclose organic solar cells in which single-walled carbon nanotubes (SWCNTs) are used as the transparent electrode. No surface modifications of the electrodes are suggested.

Given the many potential uses of such devices, there is a need for organic solar cells with improved efficiency and high performance and for a new, simple and cheap method for their preparation.

### SUMMARY OF THE INVENTION

In one aspect, the present invention provides an organic solar cell structure comprising a photoactive layer comprising at least one organic semiconductor, a first electrode and a second electrode; wherein at least one of said first and second electrodes comprises a layer which is surface-modified with a dye; said surface-modified layer being selected from a transparent conductor layer, a hole collecting layer (HCL), and an electron collecting layer (ECL).

In another aspect, the invention provides a method of making said organic solar cell structure, comprising the step of dipping the material of said at least one of the layers into a dye solution before forming the layer onto the structure.

In another aspect, the invention provides a method of making said organic solar cell structure, comprising the step of dipping a substrate coated with a transparent conductor layer into a dye solution.

In a further aspect, the invention provides uses of said solar cells in OLED, OTFT or other organic electronic devices. The invention further provides the use of modified electrode layers, as described herein, in an OLED, OTFT or other organic electronic device.

In a still further aspect, the invention provides a process for the manufacture of an organic solar cell, comprising:

a) deposition of a transparent conductor layer;
b) deposition of a photoactive layer;
c) optionally, deposition of an ECL layer;
d) optionally, deposition of a HCL layer; and
e) modification of the transparent conductor layer and/or the ECL layer and/or the HCL layer, by treatment with a dye.

### BRIEF DESCRIPTION OF THE FIGURES

FIG. 1 shows a typical device configuration used for conventional OPV structures.

FIG. 2 shows a typical device configuration used for inverted OPV structures.

FIG. 3 shows an example of dye modification on a TiO₂ surface.

FIG. 4 shows an example of dye surface modification of a flexible substrate with a TiO₂ coating in a production line.

FIG. 5 shows an example of the configuration of the OPV cell of the invention.

FIG. 6 is a schematic representation of a process for the preparation of the dye-modified electron collecting structures on inverted OPV cells.

FIG. 7 is a schematic energy level diagram for the system: ITO/ZnO/Dye/P3HT:PCBM/PEDOT:PSS/Au

FIG. 8 shows a configuration used for ITO dye-modified inverted structures.

FIG. 9 is the J-V curve for ITO/Dye/P3HT:PCBM/PEDOT:PSS/Au.

FIG. 10 is the J-V curve comparing ITO/TiO2-Dye/P3HT:PCBM/PEDOT:PSS/Au with ITO/TiO2/P3HT:PCBM/PEDOT:PSS/Au.

FIG. 11 shows an example of a dye structure, suitable for use in the invention.

FIG. 12 shows typical energy levels of a dye for use in the invention.

FIG. 13 shows the structures of the dyes used in the Examples.

### DETAILED DESCRIPTION OF THE INVENTION

The present invention relates to the modification of the surface of one or more layers in organic photovoltaic (OPV) or organic photodetector (OPD) devices.

In some embodiments, the invention relates to dye-modification of said surfaces, in particular to dye-modification of layers in electron-collecting electrodes or hole-collecting electrodes in organic photovoltaic (OPV) or organic photodetector (OPD) devices. This may comprise dye-modification of a transparent conductor layer, a HCL and/or an ECL layer.

The present inventors have provided a new, simple and cheap method for the preparation of high performance organic polymer solar cells. The method comprises modifying one or more electrode layers by surface treatment, for example with an organic dye. The dye is anchored to the surface of the transparent conducting electrode, the electron collection layer, or the hole collecting layer during the preparation of the OPV device, and serves to modify the properties of the layer to which it is attached.

Surface modification of the layers used in organic solar cells improves the general performance of the organic solar cell. The resultant OPV devices have improved properties which may include improved performance (such as higher photocurrent and/or fill factor, leading to enhanced efficiency), and reduced cost of manufacture.

The devices of the invention may also have improved OPD performance. This may open up new applications for OPD devices, for example by improving sensitivity to low light levels.

An additional benefit of the modification process of the present invention is a reduction in dark current and improvement in diode behaviour of the functionalised OPV device. This feature is beneficial for many organic electronic devices, including, but not limited to, diodes, OLEDs and OTFTs.

### Organic Solar Cells

The organic photovoltaic (OPV) architecture is formed from a series of sequentially deposited layers.

A typical organic solar cell structure may comprise an active layer and electrodes. The electrodes may comprise conducting contacts (at least one of which is a transparent conductor) and, optionally, electron collecting (ECL) or hole collecting (HCL) layers, as necessary.

Other, optional, interlayers may also be included. For example, one or more electron transport layers (ETL), or other anode or cathode interlayers, as may typically be used in OPV cells.

The layers of the organic solar cell structure may typically be deposited on a substrate. The order of the layers depends on the nature (e.g. inverted or non-inverted) of the cell. The ECL and/or the HCL layer may be absent.

### Active Layer

The active layer of the organic solar cell is a photoactive layer, deposited on top of the lower electrode structure.

The photoactive layer is responsible for absorbing photons and generating the electric charges. The photoactive layer in the structures of the invention comprises at least one organic electronic material, which is preferably an organic semiconductor material.

Preferably, the photoactive layer comprises a binary system of donor and acceptor materials, of which at least one is an organic semiconductor material. In a binary system, the acceptor material has higher electron affinity and ionisation potential than the donor material, making transfer of an electron from the donor to the acceptor energetically favourable. Providing this energy gain is large enough, the binding energy of the electron and hole pair (termed an exciton) may be overcome, allowing the charges to separate (see Reference 14).

In some embodiments, both the donor and acceptor materials are organic semiconductors. In some embodiments, an organic semiconductor donor may be combined with an inorganic semiconductor acceptor. In other embodiments, an organic semiconductor acceptor may be combined with an inorganic donor.

Suitable organic semiconductor materials may include conjugated polymers, such as polyacetylene, co-polymers and derivatives of polythiophenes, for example poly(3-hexylthiophene) (P3HT), poly(3-octyl-thiophene) (P3OT), polyfluorenes, silicon-bridged polyfluorenes, polyindenofluorenes, polycarbazoles and poly phenylene vinylenes, for example poly(phenylene-vinylene) (PPV), poly[2-methoxy-5-(2′-ethyl-hexyloxy)-1,4-phenylene vinylene] (MEH-PPV), or small molecule organic semiconductors, such as thiophene based oligomers, phthalocyanines, for example copper- and zinc-phthalocyanine. These organic semiconductor materials may be utilised in a binary system as described above. In such a binary system, these materials may be more commonly used as the donor component. However, as will be appreciated by one skilled in the art, they could also act as acceptors, depending on the relative energy levels of the other component(s).

Other suitable organic semiconductor materials may include conjugated polymers, (such as polymers or co-polymers based on the materials in the list above) or small molecules such as C60 (fullerene) or a derivative thereof, for example phenyl-C61-butyric acid methyl ester (PCBM), perylene derivatives, for example perylene tetracarboxylic derivative, bis(phenethylimido)perylene. These organic semiconductor materials may be utilised in a binary system as described above. In such a binary system, these materials may be more commonly used as the acceptor component. However, as will be appreciated by one skilled in the art, they could also act as donors, depending on the relative energy levels of the other component(s).

Suitable inorganic semiconductor materials may include cadmium selenide nanocrystals, other selenides, carbon nanotubes, cadmium sulphide, lead sulphide and others which are known in the art.

Some possible binary systems for the photoactive layer include, but are not limited to, those shown in the table below:

| Donor | Acceptor |
|---|---|
| organic conjugated polymer | small organic molecule |
| | semiconductor |
| organic conjugated polymer | organic conjugated polymer |
| small organic molecule | small organic molecule |
| semiconductor | semiconductor |
| small organic molecule | organic conjugated polymer |
| semiconductor | |
| organic conjugated polymer | inorganic semiconductor |
| inorganic semiconductor | organic conjugated polymer |

In some embodiments, the photoactive layer may comprise a blend or a bilayer of the donor and acceptor semiconductor materials.

In some embodiments, the donor and acceptor materials are present as a bilayer i.e. a layer of donor material and a layer of acceptor material.

In some embodiments, the donor and acceptor materials are present as a blend i.e. the donor material and acceptor material are mixed together to form a dispersed system.

In some embodiments, the photoactive layer comprises donor and acceptor semiconductors in 1:1 molar ratio.

In some embodiments, the photoactive layer comprises P3HT and PCBM.

Various other organic photoactive materials and systems, suitable for use in the devices of the present invention are known in the art.

The active layer thickness depends on the optoelectronic properties of the particular active layer materials selected. The thickness is typically in the range of 40 to 1000 nm, more typically 70 to 300 nm.

In some embodiments, the active layer has a thickness of less than 1000 nm, less than 700 nm, less than 500 nm, less than 300 nm, less than 200 nm or less than 100 nm.

In some embodiments, the active layer has a thickness of more than 40 nm, more than 50 nm, more than 70 nm, or more than 100 nm.

The active layer is sandwiched between two electrode structures.

### Electrodes

The electrode structures each comprise a conducting contact and, optionally, one or more interlayers (e.g. ECL or HCL).

The conducting contact serves to extract charges from the cell and convey them to the external circuit. The contact preferably has high conductivity, to reduce any voltage drop across the OPV cell.

At least one of the electrodes in the organic solar cell structure of the invention comprises a transparent or semi-transparent conductor as the conducting contact. This conductor allows light to enter the active layer of the cell and photocurrent to be extracted. The transparent conductor may be a transparent conducting oxide (TOO), preferably comprising a metal oxide including, but not limited to: Indium Tin Oxide (ITO), Fluorine-doped Tin Oxide (FTO) or aluminium doped zinc oxide (AZO), zinc-indium tin oxide (ZITO). In some embodiments, the TCO preferably comprises ITO. Alternative transparent conductors to TCO may include doped organic polymers, nanotube dispersions, thin metals etc. See e.g. reference 15 (vapour phase polymerised PEDOT, carbon nanotube sheets) and reference 16 (carbon nanotube films).

The transparent conductor thickness depends on the optoelectronic properties of the particular materials selected. The thickness is typically in the range of 30 to 1000 nm, more typically 40 to 200 nm.

In some embodiments, the transparent conductor has a thickness of less than 1000 nm, less than 700 nm, less than 500 nm, less than 300 nm, or less than 200 nm.

In some embodiments, the transparent conductor has a thickness of more than 30 nm, more than 40 nm, more than 50 nm, more than 70 nm, or more than 100 nm.

The other electrode in the organic solar cell structure of the invention may comprise any conducting contact.

In some embodiments, this conducting contact comprises a metal such as Au, Al, Ag, Pt, Pd, Cu, or Ni. In some embodiments, this is preferably a high work function metal, such as Au, Pd, or Pt. In other embodiments, this may be a low work function metal such as Al or Ag.

In some embodiments the conducting contact may comprise multiple metallic layers of different composition, such as, for example, a layer of calcium capped by a layer of aluminium.

The conducting contact may also comprise other materials such as doped conducting polymers (for example PEDOT, polyaniline etc), nanotubes, for example carbon nanotubes, dispersions of inorganic nanotubes or nanowires in an organic matrix, or other systems which are known in the art (see Refs 15 and 16, for example).

In some embodiments, this electrode in the organic solar cell structure preferably comprises a high work function conductor as the conducting contact. In some embodiments, this is a high workfunction metal, such as Au, Pd, or Pt.

The conducting contact thickness depends on the electrical and physical properties of the particular material selected. The thickness is typically in the range of 20 to 1000 nm, more typically 70 to 300 nm.

In some embodiments, the conducting contact has a thickness of less than 1000 nm, less than 700 nm, less than 500 nm, less than 300 nm, less than 200 nm, or less than 100 nm.

In some embodiments, the conducting contact has a thickness of more than 20 nm, more than 30 nm, more than 40 nm, more than 50 nm, more than 70 nm, or more than 100 nm.

An electron collecting layer (ECL) may optionally be incorporated into one of the electrodes, to better match the work function of the contact to the appropriate electronic energy level of the active layer.

Similarly, a hole collecting layer (HCL) may optionally be incorporated into the other electrode, to better match the work function of that contact to the appropriate electronic energy level of the active layer.

The ECL and HCL may also provide selectivity, facilitating transport of one charge species (i.e. electron or hole) to the contact, while blocking the other species.

An electron collecting layer (ECL) serves to collect electrons from the active layer. The ECL ideally also serves to block holes, providing electrode selectivity. In some embodiments, the ECL comprises lithium fluoride (LiF), or may include other alkali metal fluorides, oxides, carbonates and other compounds. In some embodiments, the ECL comprises a metal oxide (MOx). Examples of suitable metal oxides include, but are not limited to, titania (TiO₂), zinc oxide, tin oxide, niobium oxide, zirconium oxide and compound oxides (e.g. niobium titanium oxide).

The ECL is required if the energy levels of the contact itself are not appropriate for electron collection. In some embodiments of the present invention, a separate, distinct ECL may be absent.

A hole collecting layer (HCL) collects holes from the active layer. The HCL ideally also serves to block electrons, providing electrode selectivity. The HCL may consist of a conductive polymer such as poly(3,4-ethylenedioxythiophene) poly(styrenesulfonate) (PEDOT:PSS) or other doped polymer based on e.g. polyaniline or polyacetylene, or an inorganic material, such as a metal oxide which may include molybdenum oxide (MOx), tungsten oxide (WOx), vanadium oxide (VOx), nickel oxide NiO, or cuprous oxide Cu₂O.

In some embodiments of the present invention, the HCL may be absent. The HCL may not be not needed if the energy levels of the relevant contact are appropriate for hole collection. In some embodiments of the present invention, a separate, distinct HCL may be absent.

The thickness of the ECL and HCL layers depends on the optoelectronic properties of the particular active layer materials selected. The thickness is typically in the range of 1 to 500 nm, more typically 10 to 200 nm.

In some embodiments, the ECL has a thickness of less than 500 nm, less than 400 nm, less than 300 nm, less than 200 nm, less than 100 nm, or less than 50 nm. In some embodiments, the ECL has a thickness of more than 1 nm, more than 2 nm, more than 5 nm, more than 10 nm, or more than 20 nm.

In some embodiments, the HCL has a thickness of less than 500 nm, less than 400 nm, less than 300 nm, less than 200 nm, less than 100 nm, or less than 50 nm. In some embodiments, the HCL has a thickness of more than 1 nm, more than 2 nm, more than 5 nm, more than 10 nm, or more than 20 nm.

In some embodiments additional layers may be incorporated between the photoactive layer and the contacts, such as electron or charge transport layers.

### Substrates

Preferably, the organic solar cell structure of the invention is deposited on a substrate.

The substrate may be a transparent substrate, thus allowing light to enter the device through the substrate. Any transparent substrate may be used. The substrate may comprise, for example, glass or a transparent plastic, such as polyethylene terephthalate (PET), polyethylene naphthalate (PEN), or others which are known in the art.

Alternatively, if the top electrode layer of the OPV stack comprises a transparent conductor (e.g. as described above), the substrate need not necessarily be transparent as, in this case, light may enter the active layer through the top of the stack. Examples of non-transparent substrates that may be used include, but are not limited to, metal foil (e.g. steel foil) or metallised plastic.

### Inverted and Non-Inverted Structures

As illustrated above, a typical organic solar cell structure may comprise:
1. a transparent conductor
2. a hole collecting layer (HCL).
3. an active layer.
4. an electron collecting layer (ECL).

The structure may be deposited on a substrate. The OPV device stack may be completed by application of a further contact. The order of the layers may vary depending on whether an inverted or conventional (non-inverted) structure is desired.

In an ‘inverted’ OPV structure, an electron collecting layer (ECL) may be deposited onto the transparent conductor. The active layer is then deposited on the ECL, if present, or the transparent conductor. In the inverted structure the electrode (anode) comprising the HCL is on the top of the device stack. The OPV structure is completed by application of the top contact.

The cathode electrode stack may, for example, comprise a transparent contact, such as a TCO, combined with an ECL, such as titania. The anode electrode stack, deposited on top of the active layer, may comprise a high workfunction metal such as Au, Pt, Pd etc, etc. An HCL, such as PEDOT:PSS, may be inserted between the active layer and the anode contact.

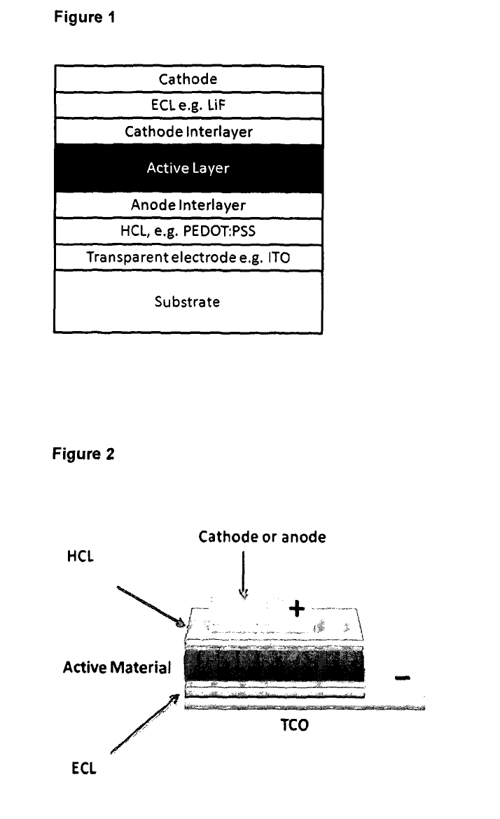

An example of an ‘inverted’ OPV structure is shown in FIG. 2. As shown in this structure, the TCO is deposited on the substrate and the (optional) ECL layer is deposited onto the TCO. The photoactive layer is deposited onto this lower electrode structure. The HCL is on the top of the device stack. A high work-function electrode may then be deposited onto the stack, and serves to collect holes and transport them to an external circuit.

In a non-inverted (conventional) OPV structure, the hole collecting layer (HCL) may be deposited onto the transparent conductor. The active layer is deposited on the HCL, if present, or onto the transparent conductor. In the non-inverted structure the electrode comprising the ECL (the cathode) is on the top of the device stack. The OPV device stack is completed by application of the top contact.

In a conventional (non-inverted) structure OPV device the TCO, deposited on the substrate, collects the holes. The HCL, if present, is deposited on the TCO, followed by the photoactive layer. Finally the cathode contact is on top of the stack. Optionally an ECL may be included between the active layer and the cathode contact. The cathode contact serves to collect electrons and transport them to the external circuit. In this embodiment the cathode contact typically consists of a low workfunction metal, such as Al, Ag. Alternatively an organic conductor may be employed. The ECL may be included if the workfunction of the contact is not well matched to the LUMO level of the active layer. An example is shown in FIG. 1.

The organic solar cell structures of the present invention may have either an inverted or a non-inverted configuration.

In some embodiments, the organic solar cell has an inverted configuration. In some embodiments, the organic solar cell has a non-inverted configuration.

### Surface Modification

In the devices of the present invention, one or more of the layers in the organic solar cell structure is functionalised. In particular, one or more of the layers making up at least one of the electrodes may be functionalised, i.e. modified in order to alter the performance of the OPV device.

The layer(s) may be functionalised by surface-modification, i.e. a surface of at least one layer in the solar cell structure is modified, preferably by treatment of the surface with a modifying substance or compound. The modifying compound is preferably a dye, as further described below.

The layer to be functionalised is preferably a layer adjacent to the active layer. The surface to be modified is preferably a surface which is in contact with the active layer. In other embodiments, however, there may be one or more optional interlayers between the modified surface and the active layer.

Preferably, the functionalised layer(s) is selected from the ECL (if present), the HCL (if present) and the transparent conductor layer.

In some embodiments, the ECL, if present, is functionalised.

In some embodiments, the ECL is present and a surface of the ECL in contact with the photoactive layer is modified.

In some embodiments, the HCL, if present, is functionalised.

In some embodiments, the HCL is present and a surface of the HCL in contact with the photoactive layer is modified.

In some embodiments, the transparent conductor layer is functionalised.

In some embodiments, the transparent conductor is adjacent to the photoactive layer and the surface of the transparent conductor layer in contact with the photoactive layer is modified.

In some embodiments, the transparent conductor layer is functionalised and the ECL, if present, is also functionalised.

In some embodiments, the transparent conductor layer is functionalised and the HCL, if present, is also functionalised.

In some embodiments, the HCL (if present) is functionalised and the ECL, if present, is also functionalised.

As described above, ‘functionalisation’ refers to modification of a surface of the relevant layer(s), preferably with a dye. In general, ‘dyes’ are compounds or substances that absorb energy (i.e. light) at particular wavelengths, due to their characteristic energy levels. A ‘dye’ used for surface modification, as described herein, may be any compound or substance capable of functionalising a layer of an OPV electrode, i.e. any compound or substance with energy levels in the appropriate range to overlap with the energy levels of the adjacent layers.

A dye for use in the present invention preferably:

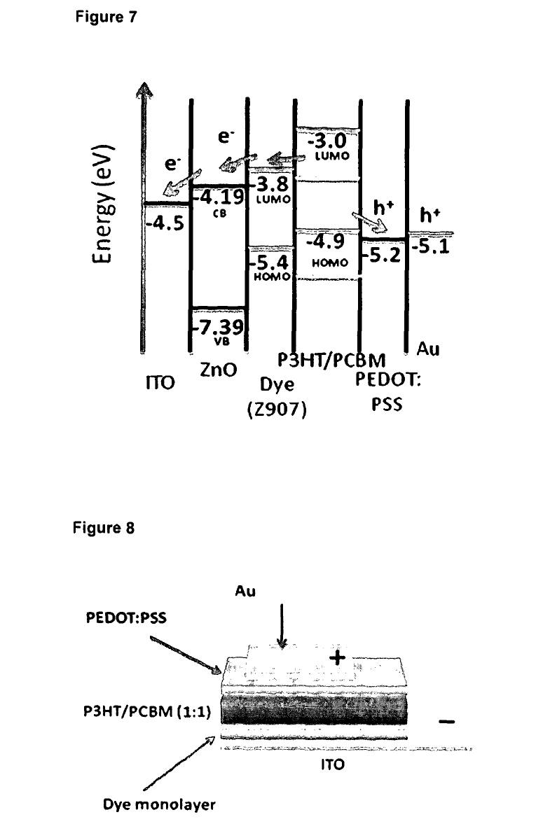

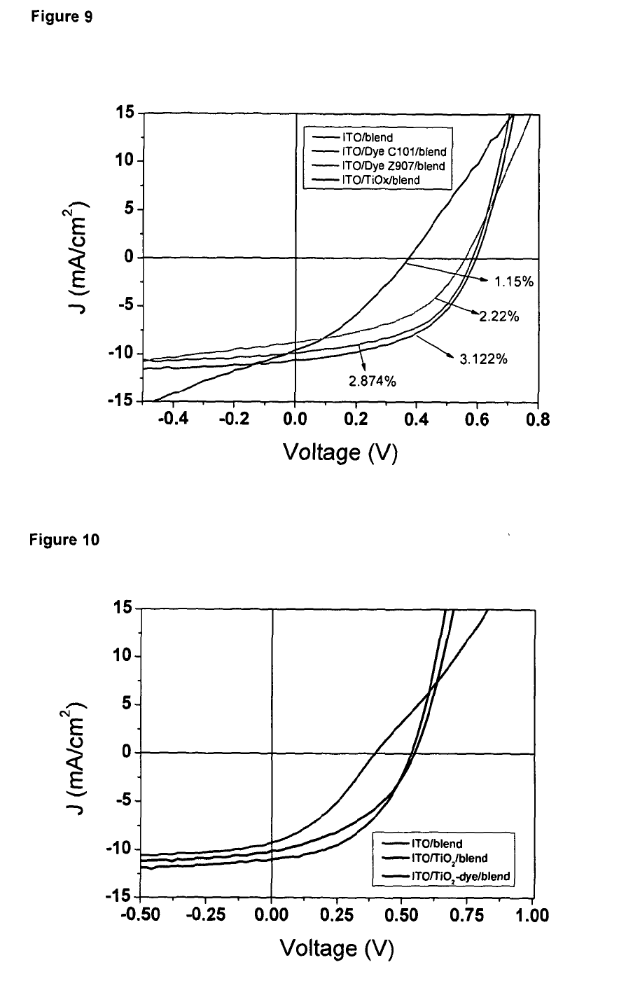

(a) has energy levels in the required range, ideally forming a cascade (intermediate step) for the appropriate charge as it is transferred from the active layer to the electrode (HCL/ECL/transparent conductor) (see FIG. 7) and
(b) has appropriate functionality to attach to the surface being modified.

The relevant energy levels (electronic orbitals) of the dye are its lowest unoccupied molecular orbital (LUMO) and its highest occupied molecular orbital (HOMO).

When the dye is used to enhance the electron collecting electrode, it functions to assist the transfer of electrons from the active layer to the electron collecting electrode and to block the transfer of holes from the active layer to that electrode (see e.g. FIG. 12).

In order to serve this function, the dye LUMO should preferably lie higher in energy than the conduction band of the metal oxide or TCO electrode to which it is attached, and should be similar in energy (for example, within about 0.2 eV) to the LUMO of the acceptor component of the active layer.

In some embodiments of the present invention, the dye has a LUMO which is within about 0.5 eV, preferably within about 0.3 eV, more preferably within about 0.2 eV, more preferably within about 0.1 eV of the LUMO of the active layer.

In some embodiments of the present invention, the active layer is a binary donor-acceptor system, and the dye has a LUMO which is within about 0.5 eV, preferably within about 0.3 eV, more preferably within about 0.2 eV, more preferably within about 0.1 eV of the LUMO of the acceptor component of the active layer.

For efficient electron transfer from dye to electrode, the energy difference between dye LUMO and electrode conduction band should be at least a few tenths of an electron volt, typically greater than e.g. 0.3 eV.

In some embodiments of the present invention, the dye has a LUMO which is greater than about 0.1 eV, preferably greater than about 0.3 eV, more preferably greater than about 0.5 eV, more preferably greater than about 0.7 eV, more preferably greater than about 1 eV of the conduction band of the active layer.

For efficient hole blocking function, the HOMO of the dye should preferably lie at least a few electron volts deeper than the HOMO of the donor component of the active layer.

In some embodiments of the present invention, the dye has a HOMO which is more than about 1 eV, preferably more than about 2 eV, more preferably more than about 3 eV, more preferably more than about 5 eV deeper than the HOMO of the active layer.

In some embodiments of the present invention, the active layer is a binary donor-acceptor system, and the dye has a HOMO which is more than about 1 eV, preferably more than about 2 eV, more preferably more than about 3 eV, more preferably more than about 5 eV deeper than the HOMO of the donor component of the active layer.

The valence band of the electrode material should lie a few tenths of an electron volt deeper than the dye HOMO; for many systems this difference is much larger, typically more than 1 eV.

In some embodiments of the present invention, the dye has a HOMO which is more than about 0.2 eV, preferably more than about 0.3 eV, more preferably more than about 0.5 eV, more preferably more than about 1 eV higher in energy than the valence band of the active layer.

For use in the present invention, it is the value of the dye HOMO and LUMO relative to the energy levels of the active layer and those of the electrode material, and not the absolute values, that are important.

The values of the dye HOMO and LUMO can be determined electrochemically using cyclic voltammetry, differential pulsed voltammetry, or photoelectron spectroscopy. It is the values for the dye attached to the electrode, rather than in isolation, which are important.

A dye for use in the present invention preferably has the following structural components:

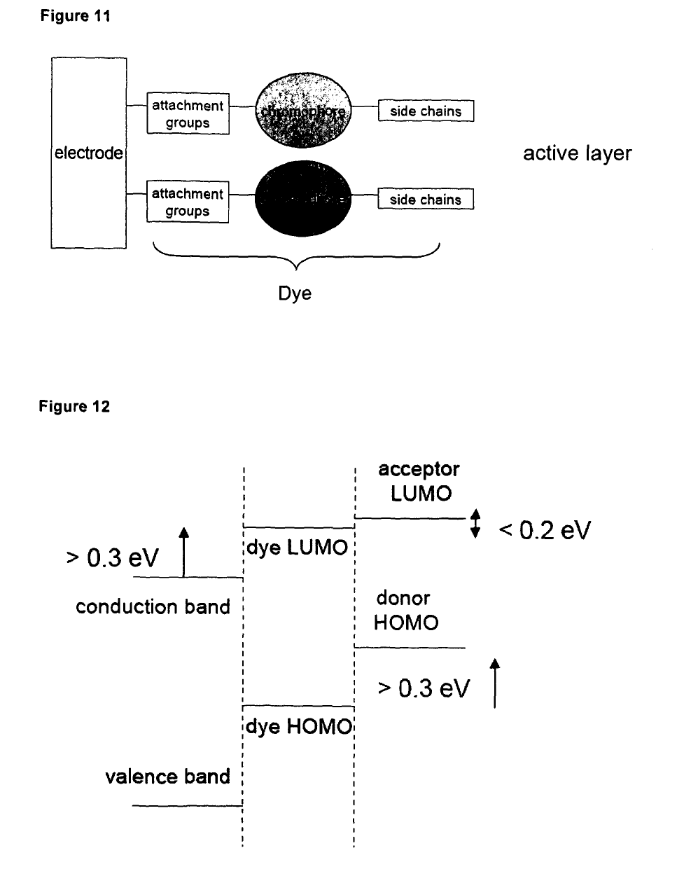

(a) a chromophore/redox centre;
(b) functional groups to bind to the oxide surface;
optionally, (c) other side groups which do not attach to the oxide surface but which influence interaction with the active layer (organic semiconductor layer). See FIG. 11.

The chromophore is responsible for the redox behaviour of the dye and it is this part of the molecule which primarily determines the HOMO-LUMO energy levels (discussed in more detail above). The chromophore may preferably comprise a pi-conjugated unit or a metal surrounded by a conjugated unit or units. In some embodiments it may include organic or organometallic centres, which may or may not be light absorbing dyes.

Examples of suitable chromophores include, but are not limited to, ruthenium bi-pyridyl complexes and other related organometallic centres (e.g. with osmium or copper replacing ruthenium, and other organic ligands, including terpyridines, cyclometallated complexes etc), porphyrins, phthalocyanines, coumarin, squarines, perylines and oligomers of typical light-absorbing polymers (e.g.: thiophenes, fluorenes, phenyl vinylenes, triphenyl amines etc).

An ‘organic interface group’, (c), may optionally be present to ensure favourable wetting of the functionalised surface by the photoactive layer. This may comprise additional side chains, added to improve compatibility with the active layer.

These may be nonpolar groups such as aliphatic side chains or phenyl or thiophene containing side chains, or they may contain polar groups such as ethers. The aliphatic/aromatic and polar/nonpolar nature of the side chains will influence the interaction with the organic active layer materials, in that like groups on the side chain and the active layer materials will encourage interaction.

The wetting behaviour of the active layer on the treated surface can be measured by measuring the polar and dispersive parts of the surface tension of the dye treated surface and the surface tension of the solution containing the active layer materials. For good wetting of the dye treated surface, the surface tension of the solution should lie within the wetting envelope of the treated surface.

Examples of such side chains include alkyl chains, alkyl ether chains, single or oligomer units of the photoactive layer such as thiophenes, fluorenes, phenyl vinylenes, triphenyl amines, fullerenes or combinations thereof.

In order for the dye to bind to the oxide surface, a suitable oxygen containing functional group or groups should be attached. The binding group, (b), is preferably a functional group which enables ligation to the electrode surface.

The dye can be bonded to the surface to be modified via various functional groups, including carboxylic groups, phosphonic acid groups, silanes, or other groups, which can interact with the surface of the layer. For example, they may interact with a metal oxide surface. Examples include, but are not limited to, COOH (carboxylate), PO₃H (phosphonate), CONH₂ (amide), SO₃H (sulphonate), and silane units.

In some embodiments, the dye may, for example, comprise a moiety having the general structure shown below:

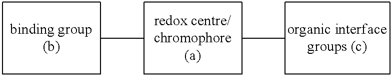

where (a), (b), and (c) are as described above. An example of this general structure is also shown in FIG. 11.

A wide range of dyes may be used, including organometallic complexes or metal-free organic dyes.

In some embodiments the dye is an amphiphilic dye.

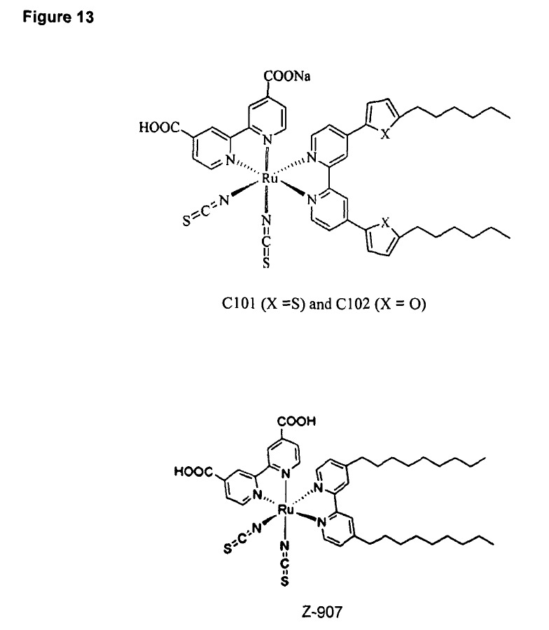

In some embodiments, the dye is a ruthenium dye such as C-101 (cis-bis(isothiocanate)(4,4′-bis(5-hexylthiophene-2-yl)-2,2′-bipyridine)(4-carboxylic acid-4′-carboxylate-2,2′-bipyridine)ruthenium(II) sodium) C-102 (cis-bis(isothiocanate)(4,4′-bis(5-hexylfuran-2-yl)-2,2′-bipyridine)(4-carboxylic acid-4′-carboxylate-2,2′-bipyridine)ruthenium(II) sodium), Z-907 (cis-Bis(isothiocyanato)(2,2′-bipyridyl-4,4′-dicarboxylato)(4,4′-di-nonyl-2′-bipyridyl)ruthenium(II)) (see FIG. 13), for example.

Examples of metal-free organic dyes include, but are not limited to acridine dyes, anthraquinone dyes, arylmethane dyes, cyanine dyes, diazonium dyes, phthalocyanine dyes, quinone-imine dyes, thiazole dyes, xanthene dyes, fluorene dyes, fluorone dyes, rhodamine dyes, etc.

The selection of dyes that absorb light in a region of the sun spectrum complementary to the absorption of the active layer may be preferred in some embodiments, as this may permit a greater absorption of the total solar spectrum.

As set out above, the dye can be bonded to the surface to be modified via various functional groups, including carboxylic groups, phosphonic acid groups, silanes, or other groups, which can interact with the surface of the layer. For example, they may interact with a metal oxide surface.

### Method of Manufacture

The manufacture of an organic solar cell according to the present invention comprises the steps of:

a) deposition of a transparent conductor layer;
b) deposition of a photoactive layer;
c) optionally, deposition of an ECL layer;
d) optionally, deposition of a HCL layer; and
e) functionalisation of:
the transparent conductor layer; and/or
the ECL layer; and/or
the HCL layer;
by treatment with a dye.

These steps may be performed in any logical order, depending on the structure of the device to be manufactured.

The deposition of the layers of the OPV may be performed by any of the presently known commercial procedures (sol-gel, chemical vapour deposition, thermal evaporation, sputtering).

This application of the dye to the appropriate layer is a simple process which does not add significantly to the total processing time or cost for production of an OPV device.

The transparent conductor, HCL or ECL material may be dipped in a dye solution for a specific time in order to bind the dye to the surface.

In some embodiments, the dye may bind to structural defects on the surface, for example due to vacancies of oxygen. For instance, if the dye contains carboxylic groups, the dye may form ester-like linkages (C═O) or carboxylate linkages ((CO)—O—) with a metal oxide layer, for example via a titanium atom, in the case of TiO₂ (See FIG. 2).

If the layer to be functionalised is already in place in a device stack, exposing the whole device stack to the dye solution potentially allows some of the dye to diffuse to the interface between the layer to be functionalised and the photoactive layer, particularly if the layer to be modified is thin, or if there are pin holes or other defects in it. For example, an HCL layer on the top of a device stack may be modified at the interface between the photoactive layer and the HCL in this way. However, there may be complications with damage to other layers if the whole device stack is immersed in the dye solution.

Preferably, therefore, the layer is treated with the dye before it is applied to the device stack. As an example, a metal oxide solution or dispersion of metal oxide nanoparticles could be treated with a dye, and then applied to the device stack using a printing/coating technique to form a functionalised HCL layer. The process of the invention can be used to modify the thin MOx layers used as the electron collection layer in inverted solar cells, This also gives an improvement in OPV device performance.

Alternatively, or additionally, in some embodiments, a substrate coated with a transparent conductor may be dipped in the dye solution. In some embodiments, a TCO-coated substrate is dipped in the dye solution.

The selection of dye functional groups and optimisation of the dye deposition process depends on the nature of the surface to be functionalised, the energy levels of teh active layer and electrodes, the type of dye, concentration, temperature solution and solvent, as would be understood by those skilled in the art.

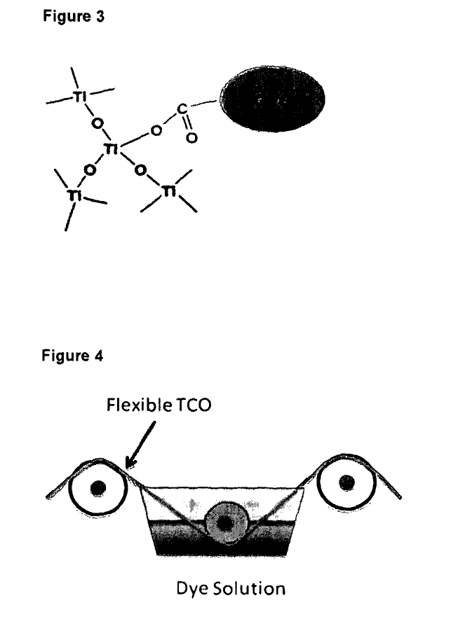

FIG. 3 shows a possible approach to the adaptation of this invention in a production line. Besides this, other procedures can be used, including but not limited to a doctor blade, inkjet printing, spin coating, spray coating, and others.

In some embodiments, un-attached dye molecules may be removed by a rinsing process, following the surface modification process.

The process does not have a significant impact on the manufacturing or materials costs because only a very small amount of dye is consumed compared with the substantial amount of dye used in other types of solar cell, such as dye-sensitised solar cells.

Preferably the amount of dye used is from 0.01 to 10 mg/m² (i.e. 0.01 to 10 mg of dye per m² surface coated). Preferably, the amount is 0.01 mg/m² or more, 0.02 mg/m² or more, 0.05 mg/m² or more, or 0.1 mg/m² or more. Preferably, the amount is 10 mg/m² or less, 1 mg/m² or less, 0.5 mg/m² or less, 0.25 mg/m² or less, or 0.1 mg/m² or less. Most preferably an amount of about 0.1 mg/m² is used.

The procedure can be easily adapted to the preparation of large areas of organic solar cells.

### Uses

The organic solar cell structures of the present invention find use in organic solar cell devices, such as OPV and OPD devices.

OPV cells grouped together to form modules may be used to provide electrical energy from a light source, such as the sun or artificial illumination. Uses of photovoltaic modules are widespread, and may include grid-tied installations (e.g. on domestic roof tops), off-grid applications (serving an isolated community) or integration into portable, consumer products.

OPD cells may be used in an application where light intensity is to be quantified by conversion to an electrical signal. Applications include ambient light detectors, optical isolators, image sensors arrays, x-ray image recording (with x-rays converted to visible radiation via a scintillation media), and medical diagnostics.

The present system can also be implemented in other optoelectronic systems, such as organic light emitting diodes (OLEDs), or sensors. The beneficial electrical properties may also be exploited in organic thin film transistors (OTFTs) or organic diodes.

### Discussion

Even though the amount of dye used in the devices and methods of the present invention is very small, a significant improvement in device efficiency may be achieved. Without wishing to be bound by theory, one hypothesis is that the presence of the dye causes a shift in energetic levels of the TCO or ECL, improving the electron collection and potentially blocking holes. For instance, if the LUMO level of the dye lies between the LUMO level of the donor material and the TCO, a cascade effect can improve the charge collection and extraction. At the same time, if the HOMO level is deep enough this can favour hole blocking, providing charge selectivity.

Dye-sensitised solar cells (DSSC) have been previously disclosed, as discussed above. However, there are clear distinctions between the current invention and DSSC technology. With DSSCs, the dye is fully responsible for the light absorption and this is its primary role. In the cells of the present invention the active layer, based on a blend of acceptor and donor organic materials is responsible for the light absorption. Furthermore, with DSSC technology, the dye has to sensitise a relatively thick film of porous titania. This leads to very long process times. In the present invention, the surface of the non-porous ITO, or a much thinner/less porous ECL or HCL surface, is treated. In addition, much lower quantities of the dye are required in the devices of the present invention compared with DSSCs, which is important for a low cost device.

Attaching a layer of dye to the surface of the TCO may permit the energetic levels of the TCO material to be modified, without the deposition of an additional layer. Using a dye with the LUMO level between the work function of the TCO material and the LUMO level of the semiconductor-polymer facilitates electron collection. In addition the HOMO level of the dye permits the blocking of holes from the polymer.

Similarly, modifying the ECL and/or HCL with dye molecules may permit improved matching of the energetic levels of the contact to the acceptor and donor, respectively, in the photoactive layer.

For example, using metal oxide layers (MOx) modified with appropriate dye molecules permits matching of the energetic levels of the electron collecting contact to the acceptor in the photoactive layer, such as the example in FIG. 7.

Without wishing to be bound by theory, it is thought that the improvement in performance following dye functionalisation, found by the present inventors, may also arise because the dye improves the selectivity of the contacts, for example a dye modified ECL forms a barrier to extraction of holes (and/or vice versa). This may lead to the observed improved response to light of the OPV cell, and also the more rectifying behaviour.

In the event that intermediate layers are present between the dye-modified surface of the transparent conductor, ECL or HCL, the same principle applies. The dye-modified surface may permit better energy matching between the intermediate layer and the functionalised layer, thus facilitating charge transport and efficiency at the relevant interface, for example.

The manufacture of the devices is a simple and inexpensive process because of the small amount of dye used in the TCO treatment, along with ease of incorporation in a processing line. A further advantage of this modification is that it can be adapted for a wide range of different TCO materials.

Improvements in device performance in the device may also be a consequence of the reduction in recombination and also a contribution of the dye to the injection of electrons, following photoexcitation of the dye.

### EXAMPLES

The following non-limiting examples are provided to illustrate the methods and devices of the invention. Other variations falling within the general scope of the present disclosure will be evident to those skilled in the art.

### Example 1

### Method of Manufacture

### Steps:

1. Cleaning Substrates: Immersion of substrates in a sequence of solvents in an ultrasonic bath, typically acetone and isopropanol.
2. The TCO is then generally deposited on the glass by a sputtering technique, and may be patterned by a lithographic process (i.e. etching with acid, following masking of the required active areas with a photoresist).
3. Deposition of the ECL: This layer can be deposited by means of spin coating, spray pyrolysis, dip-coating, doctor blade or other appropriate solution based methods and is formed by metal oxides. For instance, these solution can be formed by a sol-gel precursors (Ref 2) or by nanoparticles of metal oxides (Ref 9). Alternatively the ECL may be deposited by a vacuum based process, such as by sputtering, thermal evaporation or other physical vapour deposition process.
4. First functionalisation: The attachment of the dye can be done directly onto the TCO (avoiding step 2) or onto the ECL deposited in the step 2, by means of immersion in a dilute solution of the dye, or by applying the dye solution by drop casting, dipping, spin coating, doctor blade, gravure or other appropriate technique. Optionally, excess dye that has not bonded to the TCO or ECL surface may then be removed by a rinsing process.
5. Deposition of the photoactive layer: this layer can be formed by a bilayer system between a donor material and the acceptor, or a blend them together and deposited by common solution processing methods (e.g. spin coating, dip coating, spray coating, or other methods).
6. Deposition of the HCL: This layer can be formed either PEDOT:PSS or MOx with hole injection properties.
7. Second functionalisation: In the case of the use of MOx in the step 5, a soaking process with dye could be carried out, if necessary, to modify the HCL surface.
8. Deposition of metallic top contact: Typically a high work function metal such as Au or Ag would be used for the top electrode, either by metal evaporation or using metal paint by spin coating, ink printing, spray, doctor blade or others methods.

### Results:

### 1. ITO Surface Modification of Inverted OPV Structures:

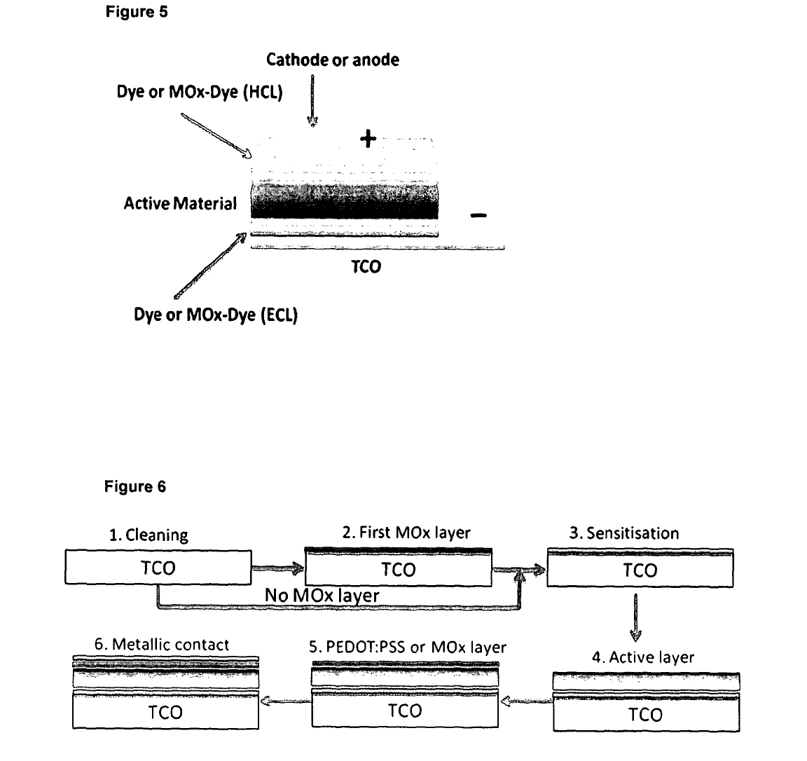

Currently, we have carried out studies modifying ITO surface using two different commercial dyes (C101 and Z907), in both cases efficiencies near to 3% were reached versus the bare substrate without modification (less 1.5%), these results clearly indicate, that this simple surface modification method is sufficient to achieve enhanced devices efficiencies. The device structure studied is shown in the FIG. 5

The surface modification process was carried out by dipping a cleaned ITO substrate in a solution 20 mM of C101 (Refs 10, 11) or Z907 (Ref 12) dye using as solvent a mixture of 1:1 acetonitrile:t-butanol, and heating at 80 C for two hours. Afterwards, the substrate was removed and washed with acetonitrile in order to remove the non anchored dye. The photoactive layer, a 250 nm layer of P3HT:PCM (1:1) was spin-cast from solution chlorobenzene. Finally, a thin layer of PEDOT:PSS (40 nm) was spin coated onto the active layer, and a layer of gold was evaporated on the top (100 nm).

### 2. TiO₂ Collecting Electron Layer Modification of Inverted OPV Structures:

Inverted devices using a thin spin coated TiO₂ (ECL) layer were prepared following a sol-gel method (Ref 13). Following curing, this layer was modified by dipping in a dye solution (C101 Acetonitrile/butanol, 1:1). Subsequent layers were deposited according to the description above.

FIG. 6 shows the IV curves of devices with and without a TiO₂ electron collecting layer. The modification of the TiO₂ layer improves as minimum the current density of the devices in 10%.

### REFERENCES

(1) Mihailetchi, V. D.; Koster, L. J. A.; Blom, P. W. M. Applied Physics Letters 2004, 85, 970-972.
(2) Waldauf, C.; Morana, M.; Denk, P.; Schilinsky, P.; Coakley, K.; Choulis, S. A.; Brabec, C. J. Applied Physics Letters 2006, 89, 233517.
(3) Shirakawa, T.; et al. Journal of Physics D: Applied Physics 2004, 37, 847.
(4) White, M. S.; Olson, D. C.; Shaheen, S. E.; Kopidakis, N.; Ginley, D. S. Applied Physics Letters 2006, 89, 143517.
(5) Kyaw, A. K. K.; Sun, X. W.; Jiang, C. Y.; Lo, G. Q.; Zhao, D. W.; Kwong, D. L. Applied Physics Letters 2008, 93, 221107.
(6) Kuwabara, T.; Nakayama, T.; Uozumi, K.; Yamaguchi, T.; Takahashi, K. Solar Energy Materials and Solar Cells 2008, 92, 1476-1482.
(7) Li, C. Y.; Wen, T. C.; Lee, T. H.; Guo, T. F.; Huang, J. C. A.; Lin, Y. C.; Hsu, Y. J. Journal of Materials Chemistry 2009, 19, 1643-1647.
(8) Thavasi, V.; Renugopalakrishnan, V.; Jose, R.; Ramakrishna, S. Materials Science & Engineering R-Reports 2009, 63, 81-99.
(9) Hau, S. K.; Yip, H.-L.; Baek, N. S.; Zou, J.; O'Malley, K.; Jen, A. K.-Y. Applied Physics Letters 2008, 92, 253301.
(10) Qin, H.; Wenger, S.; Xu, M.; Gao, F.; Jing, X.; Wang, P.; Zakeeruddin, S. M.; Gratzel, M. Journal of the American Chemical Society 2008, 130, 9202-+.
(11) Shi, D.; Pootrakulchote, N.; Li, R. Z.; Guo, J.; Wang, Y.; Zakeeruddin, S. M.; Gratzel, M.; Wang, P. Journal of Physical Chemistry C 2008, 112, 17046-17050.
(12) Ravirajan, P.; Peiro, A. M.; Nazeeruddin, M. K.; Graetzel, M.; Bradley, D. D. C.; Durrant, J. R.; Nelson, J. Journal of Physical Chemistry B 2006, 110, 7635-7639.
(13) Lee, K.; Kim, J. Y.; Park, S. H.; Kim, S. H.; Cho, S.; Heeger, A. J. Advanced Materials 2007, 19, 2445.
(14) Halls et al, Phys. Rev. B 1999, 60, 5721-5727
(15) Admassie et al, Solar Energy Materials and Solar Cells, 2006, 90, 2, 133-141
(16) Van de Lagemaat et al. Appl. Phys. Lett., 2006, 88, 23, 233503

1. An organic solar cell structure comprising:
a photoactive layer comprising at least one organic semiconductor, a first electrode and a second electrode;
wherein at least one of said first and second electrodes comprises a layer which is surface-modified with a dye;
said surface-modified layer being selected from a transparent conductor layer, a hole collecting layer (HCL), and an electron collecting layer (ECL).

2. An organic solar cell structure according to claim 1, wherein the first electrode comprises an electron collecting layer (ECL) and a surface of the ECL is modified with a dye.

3. An organic solar cell structure according to claim 1, wherein the second electrode comprises a hole collecting layer (HCL) and a surface of the HCL is modified with a dye.

4. An organic solar cell structure according to claim 1 wherein a surface of the transparent conductor layer is modified with a dye.

5. An organic solar cell structure according to claim 1 wherein said dye is a compound having energy levels in the required range to form a cascade for the appropriate charge as it is transferred from the active layer to the electrode.

6. An organic solar cell structure according to claim 1 wherein the modified surface is a surface which is in contact with the photoactive layer.

7. An organic solar cell structure according to claim 1, wherein the transparent conductor layer comprises a transparent conducting oxide (TCO).

8. An organic solar cell structure according to claim 1 wherein the transparent conductor comprises Indium Tin Oxide (ITO).

9. An organic solar cell structure according to claim 1 wherein said dye has the general structure:

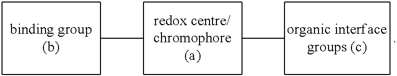

10. An organic solar cell structure according to claim 9 wherein said redox centre/chromophore (a) is selected from a π conjugated unit or a metal surrounded by a conjugated unit or units.

11. An organic solar cell structure according to claim 1 wherein said dye is selected from organometallic complexes, metal free organic dyes; acridine dyes, anthraquinone dyes, arylmethane dyes, cyanine dyes, diazonium dyes, phthalocyanine dyes, quinone-imine dyes, thiazole dyes, xanthene dyes, fluorene dyes, fluorone dyes, rhodamine dyes, ruthenium bi pyridyl complexes and related organometallic centres, porphyrins, phthalocyanines, coumarin, squarines, perylines, and oligomers of light-absorbing polymers.

12. (canceled)

13. An organic solar cell structure according to claim 1 wherein said dye is covalently bonded to the surface via a functional group selected from phosphonate, sulphonate, carboxylate, amide, and silane.

14. (canceled)

15. An organic solar cell structure according to claim 1 wherein the first electrode comprises a transparent conductor and the second electrode comprises a high work function contact.

16. An organic solar cell structure according to claim 1 which has an inverted OPV structure.

17. An organic solar cell structure according to claim 1 wherein the second electrode comprises a transparent conductor and the first electrode comprises a low work function contact.

18. An organic solar cell structure according to claim 1 which has a conventional (non-inverted) OPV structure.

19. An organic solar cell structure according to claim 1 which is applied to a substrate.

20. A method of making an organic solar cell structure according to claim 1, said method comprising the steps of:
a) dipping the material of said at least one of the layers into a dye solution before forming the layer onto the structure; or
b) dipping a substrate coated with a transparent conductor layer into a dye solution.

21. (canceled)

22. (canceled)

23. A process for the manufacture of an organic solar cell, comprising:
a) deposition of a transparent conductor layer;
b) deposition of a photoactive layer;
c) optionally, deposition of an ECL layer;
d) optionally, deposition of a HCL layer; and
e) modification of the transparent conductor layer and/or the ECL layer and/or the HCL layer, by treatment with a dye.

24. A process according to claim 23, wherein modification comprises immersion of the product of step a), step c) and/or step d) in a dye solution.
